(19) United States
(12) Patent Application Publication
(10) Pub. No.: US 2013/0222002 A1
(43) Pub. Date: Aug. 29, 2013

(54) CABLE WITH WIRE DISCONNECTION DETECTION FUNCTION

(71) Applicant: HITACHI CABLE, LTD., (US)

(72) Inventors: Hirotaka ESHIMA, Hitachi (JP); Takahiro FUTATSUMORI, Hitachi (JP)

(73) Assignee: HITACHI CABLE, LTD., Tokyo (JP)

(21) Appl. No.: 13/780,577

(22) Filed: Feb. 28, 2013

(30) Foreign Application Priority Data
Feb. 29, 2012 (JP) 2012-044391

(51) Int. Cl. G01R 31/02

(52) U.S. Cl. CPC G01R 31/023
USPC 324/750.15

(57) ABSTRACT

A cable with a wire disconnection detection function includes a detecting wire including a conductor formed by twisting a plurality of strands, and a detected wire including a conductor formed by twisting a plurality of the strands. A twist pitch of the conductor of the detecting wire is longer than that of the conductor of the detected wire.

The present application is based on Japanese patent application No. 2012-044391 filed on Feb. 29, 2012, the entire contents of which are incorporated herein by reference.

### BACKGROUND OF THE INVENTION

1. Field of the Invention

The invention relates to a cable with a wire disconnection detection function capable of predicting a wire disconnection.

2. Description of the Related Art

A cable used in a movable portion such as a wiring for a bent portion of a robot and for an in-wheel motor of a vehicle is likely to be subject to a wire disconnection by being repeatedly bent. Therefore, it is necessary to quickly predict the wire disconnection to take some measure, e.g., prompting the replacement of the cable.

JP-A-2006-32060 discloses a cable with a wire disconnection detection function capable of predicting a cable disconnection.

As shown in FIG. 5, proposed by JP-A-2006-32060 is the cable 51 with the wire disconnection detection function that is provided with a detecting wire 52 formed by providing an insulation 52b on an outer periphery of a conductor 52a composed of plural twisted strands, six detected wires 53 each formed by providing an insulation 53b around a conductor 53a composed of plural twisted strands and arranged to surround around the detecting wire 52, and a sheath 54 provided on the outermost periphery so as to cover the detecting wire 52 as well as the detected wires 53.

The cable 51 with the wire disconnection detection function is constructed such that the flex life of the detecting wire 52 is made to be shorter than that of the detected wire 53 by forming the conductor 52a of the detecting wire 52 to have a thicker strand diameter than that of the conductor 53a of the detected wire 53 or by using different materials for the strand of the conductor 52a of the detecting wire 52 and the strand of the conductor 53a of the detected wire 53.

### SUMMARY OF THE INVENTION

The conventional cable with the wire disconnection detection function must use two types of strand having different diameters or formed of different materials. Therefore, problems arise that the manufacturing cost is increased and the management of the strands is complicated.

Accordingly, it is an object of the invention to provide a cable with a wire disconnection detection function that can be made of a single type of strand.

(1) According to one embodiment of the invention, a cable with a wire disconnection detection function comprises:
a detecting wire comprising a conductor formed by twisting a plurality of strands; and
a detected wire comprising a conductor formed by twisting a plurality of the strands,
wherein a twist pitch of the conductor of the detecting wire is longer than that of the conductor of the detected wire.

In the above embodiment (1) of the invention, the following modifications and changes can be made.
(i) The cable comprises a plurality of ones of the detected wire being spirally wounded along an outer periphery of the detecting wire.
(ii) The number of strands used for the conductor of the detecting wire is less than the number of strands used for the conductor of the detected wire.
(iii) The cable comprises a plurality of ones of the detecting wire each comprising a conductor with a different twist pitch.
(iv) The twist pitch of the conductor of the detecting wire is 1.6 to 5 times longer than that of the conductor of the detected wire.

### POINTS OF THE INVENTION

According to one embodiment of the invention, a cable with a wire disconnection detection function is constructed such that the twist pitch of the conductor of a detecting wire is longer than that of the conductor of a detected wire. Here, if a same type of strand is twisted with different twist pitches, larger stress is concentrated on the strand with the longer twist pitch. Therefore, the detecting wire with the longer twist pitch can be broken earlier than the detected wire with the shorter twist pitch when repeatedly bending the cable comprised of the detecting wire and the detected wire. Thus, the cable with the wire disconnection detection function can be made only of a single type of strand by differentiating the twist pitch.

### BRIEF DESCRIPTION OF THE DRAWINGS

Next, the present invention will be explained in more detail in conjunction with appended drawings, wherein:

FIG. 1 is a cross sectional view showing a cable with wire disconnection detection function in an embodiment of the present invention;

FIG. 2 is an explanatory diagram illustrating a left-and-light 90-degree bending test in the invention;

FIG. 3 is a graph showing a result of the left-and-light 90-degree bending test in the invention;

FIG. 4 is a cross sectional view showing a cable with wire disconnection detection function in another embodiment of the invention; and

FIG. 5 is a cross sectional view showing a conventional cable with wire disconnection detection function.

### DETAILED DESCRIPTION OF THE PREFERRED EMBODIMENTS

Embodiments of the invention will be described below in conjunction with the appended drawings.

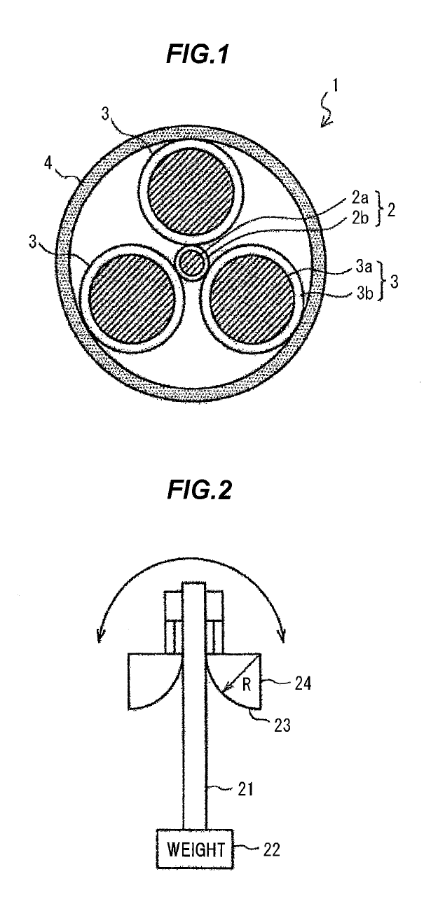

FIG. 1 is a cross sectional view showing a cable with wire disconnection detection function in the present embodiment.

As shown in FIG. 1, a cable with wire disconnection detection function 1 is provided with a detecting wire 2 having a conductor 2a formed by twisting plural strands, detected wires 3 each having a conductor 3a formed by twisting plural strands and a sheath 4 provided on the outermost periphery so as to cover the detecting wire 2 as well as the detected wires 3. Although one detecting wire 2 and three detected wires 3 are provided in the present embodiment, the number of the detecting wires 2 may be not less than two and the number of the detected wires may be not more than two or not less than four.

The detecting wire 2 is composed of the conductor 2a and an insulation 2b provided on an outer periphery thereof. Meanwhile, the detected wire 3 is composed of the conductor 3a and an insulation 3b provided on an outer periphery thereof. In the present embodiment, the strand used for the conductor 2a of the detecting wire 2 and the strand used for the conductor 3a of the detected wire 3 are the same (e.g., a copper alloy strand). Although the same material (e.g., a fluorine resin material) is used here for both the insulations 2b and 3b, different materials may be used.

In the cable with wire disconnection detection function 1 of the present embodiment, a twist pitch of the conductor 2a of the detecting wire 2 is longer than that of the conductor 3a of the detected wire 3. Note that, the twist pitch refers to a length along a longitudinal direction of the conductor 2a or 3a from a given position A to a position B which is the same circumferential position as the position A when a strand is spirally wound a single turn around the conductor 2a or 3a from the position A along an outer periphery of the conductor 2a or 3a to the position B.

Stress acts on the cable with wire disconnection detection function 1 when the cable with wire disconnection detection function 1 is bent, which produces a state similar to that of pulling the cable with wire disconnection detection function 1 in a longitudinal direction. Each strand becomes closer to straight as the twist pitch becomes longer, and strain in each strand caused when pulling the cable with wire disconnection detection function 1 in the longitudinal direction becomes larger. Conversely, each strand is in a state of being coiled several times when the twist pitch is short, strain in each strand caused when pulling the cable with wire disconnection detection function 1 in the longitudinal direction becomes smaller. In other words, forming the conductor 2a of the detecting wire 2 to have a longer twist pitch than that of the conductor 3a of the detected wire 3 allows the flex life of the detecting wire 2 to be shorter than that of the detected wire 3.

The inventors confirmed by experiments that the flex life is shortened by increasing the twist pitch. The experimental result will be explained.

Testing insulted wires having conductors with twist pitches of 5 mm, 12 mm and 30 mm were made and a left-and-light 90-degree bending test in accordance with IEC 60227-2 was conducted. A group of sixty 0.08 mm-diameter copper alloy strands was used as a conductor (cross sectional area of 0.3 mm²) and a fluorine resin material was used as an insulator.

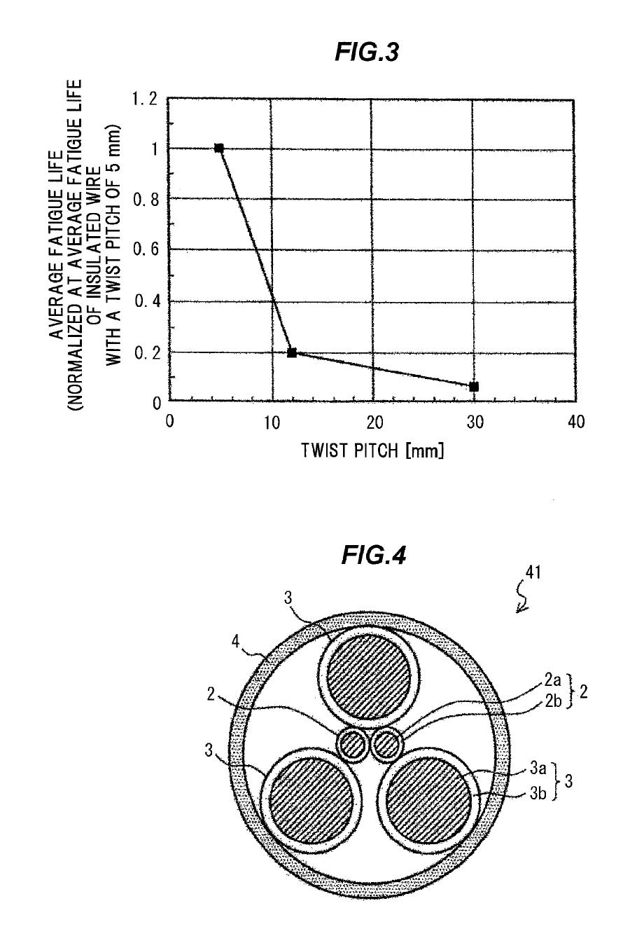

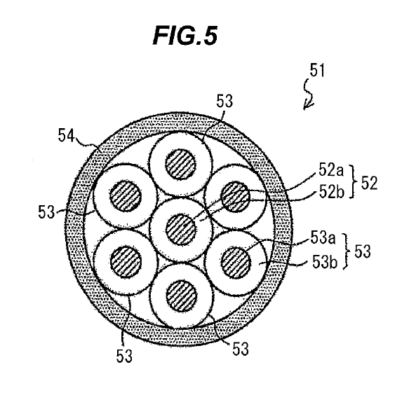

In the left-and-light 90-degree bending test, an upper portion of a testing insulated wire 21 is repeatedly bent at 90 degrees to right and left in a state that a weight 22 of 100 g is fixed to an end of the insulated wire 21, as shown in FIG. 2. A jig 24 having curved surfaces 23 which serve as a guide when bending the insulated wire 21 to right and left is located at the upper portion of the insulated wire 21. Here, the bending radius R of the curved surface 23 of the jig 24 is 10 mm. In addition, five insulated wires 21 were made for each twist pitch, the bending test was conducted thereon and each average fatigue life was calculated. FIG. 3 shows the result.

As shown in FIG. 3, it is understood that the average fatigue life decreases as the twist pitch increases. After preliminarily obtaining a graph as is shown in FIG. 3, the respective twist pitches of the conductors 2a and 3a are determined so that wire disconnection certainly occurs earlier in the detecting wire 2 than in detected wire 3. In view of the results of FIG. 3, the twist pitch of the conductor 2a of the detecting wire 2 is preferably 1.6 times to 5 times longer than that of the conductor 3a of the detected wire 3.

In addition, in the present embodiment, the detecting wire 2 is arranged linearly in the middle of the cable with wire disconnection detection function 1 and the detected wires 3 are spirally arranged along the outer periphery of the detecting wire 2. This allows the flex life of the detecting wire 2 to be shorter than that of the detected wire 3 and it is possible to surely predict wire disconnection.

Furthermore, in the present embodiment, the number of the strands used for the conductor 2a of the detecting wire 2 is less than the number of the strands used for the conductor 3a of the detected wire 3. This is to reduce a diameter of the detecting wire 2 as much as possible so that thickening of the cable with wire disconnection detection function 1 is suppressed by having such a detecting wire 2. In addition, when the number of the strands used for the conductor 2a of the detecting wire 2 is reduced, each strand of the conductor 2a of the detecting wire 2 becomes more closer to straight and the flex life is further shortened. Therefore, an effect of enabling the more reliable prediction of wire disconnection is obtained.

As described above, the cable with wire disconnection detection function 1 of the present embodiment is provided with the detecting wire 2 having the conductor 2a formed by twisting plural strands and the detected wires 3 each having the conductor 3a formed by twisting plural strands, and the twist pitch of the conductor 2a of the detecting wire 2 is longer than that of the conductor 3a of the detected wire 3.

In case that the same strands are twisted with different twist pitches, larger stress is concentrated on the strand with a longer twist pitch. Therefore, the detecting wire 2 is broken earlier than the detected wire 3 when repeatedly bending the cable with wire disconnection detection function 1.

In other words, according to the invention, the flex life of the detecting wire 2 can be shorter than that of the detected wire 3 even when the detecting wire 2 and the detected wire 3 are formed of the same strand, and it is possible to realize the cable with wire disconnection detection function 1 which can be manufactured from one type of strand. Therefore, as compared to the conventional cable with wire disconnection detection function using two types of strands, it is possible to reduce the cost and it is easy to manufacture since it is not necessary to manage the strands.

As a wire disconnection detection system, it is possible to use, e.g., a system which measures electrical resistance of the conductor 2a of the detecting wire 2, judges that the conductor 2a of the detecting wire 2 is broken when the measured electrical resistance exceeds a present threshold value, and thereby predicts disconnection of the detected wire 3 even though it is not mentioned in the present embodiment. A method of judging the disconnection of the conductor 2a of the detecting wire 2 is not limited to measurement of electrical resistance, and various methods, such as a method in which reflection of an incident radio frequency pulse is measured, are applicable.

Next, another embodiment of the invention will be described.

A cable with wire disconnection detection function 41 shown in FIG. 4 basically has the same configuration as the cable with wire disconnection detection function 1 in FIG. 1 but is provided with plural (two in the present embodiment) detecting wires 2 having conductors 2a with different twist pitches.

In the cable with wire disconnection detection function 41, since the twist pitch of the conductor 2a is different between the two detecting wires 2, the detecting wire 2 having the conductor 2a with a longer twist pitch is firstly broken and the detecting wire 2 having the conductor 2a with a shorter twist pitch is then broken, which allows disconnection of the detected wire 3 to be predicted in stages.

Note that, although two detecting wires 2 are provided here, three or more detecting wires 2 may be provided so that it is possible to predict in multistage.

The invention is not intended to be limited to the embodiments and various changes can be made without departing from the gist of the invention.

What is claimed is:

1. A cable with a wire disconnection detection function, comprising:
a detecting wire comprising a conductor formed by twisting a plurality of strands; and
a detected wire comprising a conductor formed by twisting a plurality of the strands,
wherein a twist pitch of the conductor of the detecting wire is longer than that of the conductor of the detected wire.

2. The cable according to claim 1, comprising:
a plurality of ones of the detected wire being spirally wounded along an outer periphery of the detecting wire.

3. The cable according to claim 1, wherein the number of strands used for the conductor of the detecting wire is less than the number of strands used for the conductor of the detected wire.

4. The cable according to claim 1, comprising a plurality of ones of the detecting wires each comprising a conductor with a different twist pitch.

5. The cable according to claim 1, wherein the twist pitch of the conductor of the detecting wire is 1.6 times to 5 times longer than that of the conductor of the detected wire.
